(19) United States
(12) Patent Application Publication
(10) Pub. No.: US 2023/0051210 A1
(43) Pub. Date: Feb. 16, 2023

(54) IN-SITU VACUUM REACTION SYSTEM FOR DYNAMICALLY DETECTING DEFECTS

(71) Applicant: Yangtze Delta Region Institute (Huzhou), University of Electronic Science and Technology of China, Huzhou City (CN)

(72) Inventors: Fan DONG, Huzhou City (CN); Ye HE, Huzhou City (CN); Qin REN, Huzhou City (CN); Yanjuan SUN, Huzhou City (CN); Jianping SHENG, Huzhou City (CN)

(73) Assignee: Yangtze Delta Region Institute (Huzhou), University of Electronic Science and Technology of China, Huzhou City (CN)

(21) Appl. No.: 17/881,794

(22) Filed: Aug. 5, 2022

(30) Foreign Application Priority Data
Aug. 10, 2021 (CN) 202110915593.4

(51) Int. Cl. G01N 24/10

(52) U.S. Cl. CPC G01N 24/10

(57) ABSTRACT

Disclosed is an in-situ vacuum reaction system for dynamically detecting defects, which includes an electron paramagnetic resonance spectrometer, an in-situ vacuum reaction chamber, a gas supply unit, a vacuum unit, an illumination unit, a temperature control unit and a mixing bottle, the in-situ vacuum reaction chamber is arranged inside a detection cavity of the electron paramagnetic resonance spectrometer, the gas supply unit is connected to the mixing bottle through a pipeline, and the mixing bottle is connected to a gas inlet of the in-situ vacuum reaction chamber through a pipeline, the vacuum unit is connected to the gas inlet of the in-situ vacuum reaction chamber through a pipeline, the illumination unit is arranged corresponding to a detachable window of the electron paramagnetic resonance spectrometer, and the temperature control unit is connected to the electron paramagnetic resonance spectrometer through a pipeline.

### CROSS-REFERENCE TO RELATED APPLICATIONS

This application claims priority to Chinese Utility Application No. 202110915593.4, filed on Aug. 10, 2021. The disclosure of the application is incorporated herein for all purposes by reference in its entirety.

### TECHNICAL FIELD

The present disclosure belongs to the technical field of material detection, and more particularly, relates to an in-situ vacuum reaction system for dynamically detecting defects.

### BACKGROUND

Defects can not only regulate the microstructure of catalysts and the macroscopic appearance of catalytic performance, but also provide active centers for the adsorption and activation of molecules. With the transition of defects from static system to dynamic system, surface active centers, reactive phases and surface structure also change during the reaction process. However, the commonly used defect characterization techniques and means, including electron microscopy technique and spectroscopy technique, are mainly used for the static analysis of catalyst defects before and after the reaction. For dynamic in-situ identification methods, although some in-situ detection methods have been disclosed, there is still a lack of general methods for defect characterization. Restricted by the limitations of in-situ detection methods that match the actual reaction process, understanding the nature of defect changes is a major challenge.

In recent years, the dynamic change of defects (which act as common active centers in the reaction process) in the catalytic reaction process has been gradually confirmed by experts, and the reversible change of defects has also been listed as a research focus. The surface state is different from the state presented by the material characterization during the reaction process, it is urgent to obtain in-situ characterization data in the catalytic reaction process to understand the reaction process in depth. Although the actual site, mode of action, and dynamic changes of defect in the reaction process have gradually attracted attention, however, the observed phenomenon and understanding are still relatively preliminary. The detection conditions of the in-situ method to obtain the defect signal are relatively extreme, for example, both in-situ TEM and in-situ SEM need to be tested under vacuum conditions, which are inconsistent with the actual reaction conditions and cannot accurately reflect the real-time changes of material defects during the reaction process. Moreover, restricted by the limitations of in-situ detection methods that match the actual reaction process, understanding the nature of defect changes is a major challenge. There is still a lack of understanding of the deep microscopic mechanisms in the physical and chemical transformation process of defect changes, and it is still a huge challenge to break through the limitations of existing research.

Electron Paramagnetic Resonance Spectrometer (EPR), which can observe electronic behavior (dynamics) within molecules and analyze various microscopic phenomena by identifying the electronic environment, is widely used in the research of catalytic reaction mechanism and crystal defects, and can realize qualitative and quantitative analysis of defects. However, Bruker electron paramagnetic resonance spectrometer can only analyze defects under the conditions of temperature change and added light, and the detection of defects still has limitations.

### SUMMARY

The purpose of the present disclosure is to address the deficiencies existing in the prior art, and to provide an in-situ vacuum reaction system for dynamically detecting defects.

For realizing the above-mentioned purpose, the technical schemes of the present disclosure include:

An in-situ vacuum reaction system for dynamically detecting defects, which includes an electron paramagnetic resonance spectrometer, an in-situ vacuum reaction chamber, a gas supply unit, a vacuum unit, an illumination unit, a temperature control unit and a mixing bottle, the in-situ vacuum reaction chamber is arranged inside a detection cavity of the electron paramagnetic resonance spectrometer, the gas supply unit is connected to the mixing bottle through a pipeline, and the mixing bottle is connected to a gas inlet of the in-situ vacuum reaction chamber through a pipeline, the vacuum unit is connected to the gas inlet of the in-situ vacuum reaction chamber through a pipeline, the illumination unit is arranged corresponding to a detachable window of the electron paramagnetic resonance spectrometer, and the temperature control unit is connected to the electron paramagnetic resonance spectrometer through a pipeline.

Further, the in-situ vacuum reaction chamber includes a quartz reaction tube, a connecting part, a gas inlet pipeline, a stainless steel pipeline, a first valve, a second valve and a composite vacuum gauge, an upper end of the connecting part is connected with a lower end of the stainless steel pipeline, and a lower end of the connecting part is connected with the quartz reaction tube by a threaded connection, an exhaust channel is formed between an outer wall of the gas inlet pipeline and inner walls of the quartz reaction tube, the stainless steel pipeline and the connecting part, and the first valve, the second valve and the composite vacuum gauge are connected with the stainless steel pipeline.

Further, an outer diameter of the quartz reaction tube is 5-10 mm, and an inner diameter of the quartz reaction tube is 4-9 mm.

Further, a length of the quartz reaction tube is 90-110 mm.

Further, an outer diameter of the connecting part is 20 mm.

Further, a length of the connecting part is 66 mm.

Further, the material of the gas inlet pipeline is polyoxymethylene.

Further, a length of the gas inlet pipeline is 150-200 mm.

Further, the vacuum unit includes a two-stage pump.

Further, the two-stage pump includes a mechanical pump and a molecular pump.

Compared with the prior art, the present disclosure has the following advantages and beneficial effects: the in-situ vacuum reaction system for dynamically detecting defects of the present disclosure is provided based on the existing Bruker EMX nano electron paramagnetic resonance spectrometer, which is realized by adding an in-situ vacuum reaction chamber, a gas supply unit, a vacuum unit, an illumination unit, a temperature control unit and a mixing bottle. The system of the present disclosure can realize the real-time monitoring of materials under in-situ reaction conditions such as adding light, aeration, temperature change, vacuum and the like during the testing process. In addition, while the testing conditions match the actual reaction, extreme reactions can also be designed on the system of the present disclosure to verify the experimental conjecture.

### BRIEF DESCRIPTION OF THE DRAWINGS

The present disclosure will be further described below in conjunction with the accompanying drawings and embodiments.

FIG. 1 is a schematic diagram of an in-situ vacuum reaction system for dynamically detecting defects of the present disclosure;

FIG. 2 is a structural schematic diagram of an in-situ vacuum reaction chamber of the present disclosure; and

FIG. 3 is a graph of the real-time defect signal changes measured by in-situ EPR for TiO2 materials with different initial defects under photocatalytic adsorption, reaction and light-off conditions.

### DETAILED DESCRIPTION

In order to make the purpose of the present disclosure, the technical problem to be solved and the technical solution clearer, the present disclosure will be further described below with reference to the accompanying drawings and specific embodiments.

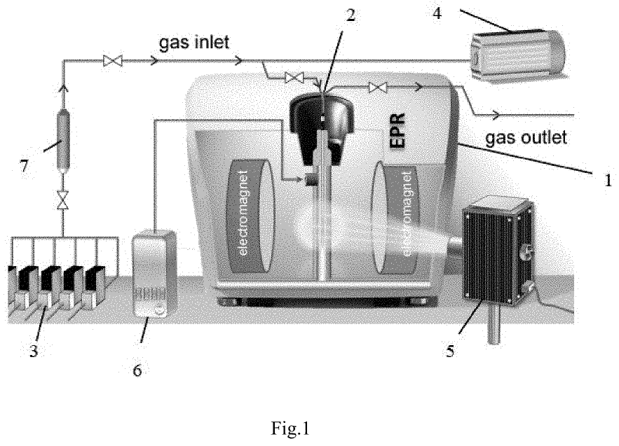

FIG. 1 is a schematic diagram of the in-situ vacuum reaction system for dynamically detecting defects of the present disclosure, which includes an electron paramagnetic resonance spectrometer 1, an in-situ vacuum reaction chamber 2, a gas supply unit 3, a vacuum unit 4, an illumination unit 5, a temperature control unit 6 and a mixing bottle 7, the in-situ vacuum reaction chamber 2 is placed inside the detection cavity of the electron paramagnetic resonance spectrometer 1, the gas supply unit 3 is connected to the mixing bottle 7 through a pipeline, and the mixing bottle 7 is connected to a gas inlet of the in-situ vacuum reaction chamber 2 through a pipeline, the vacuum unit 4 is connected to the gas inlet of the in-situ vacuum reaction chamber 2 through a pipeline, the illumination unit 5 is arranged in front of the detachable window at the front end of the electron paramagnetic resonance spectrometer 1, and the temperature control unit 6 is connected to the electron paramagnetic resonance spectrometer 1 through a pipeline.

The in-situ vacuum reaction system for dynamically detecting defects of the present disclosure is provided based on the existing Bruker EMX nano electron paramagnetic resonance spectrometer 1, it is realized by adding an in-situ vacuum reaction chamber 2, a gas supply unit 3, a vacuum unit 4, a illumination unit 5, a temperature control unit 6 and a mixing bottle 7, etc.

As shown in FIG. 2, the in-situ vacuum reaction chamber 2 includes a quartz reaction tube 21, a connecting part 22, a gas inlet pipeline 23, a stainless steel pipeline 24, a valve a 25, a valve b 26 and a composite vacuum gauge 27.

The outer diameter of the quartz reaction tube 21 is 5-10 mm, the inner diameter is 4-9 mm, and the length is 90-110 mm. The quartz reaction tube 21 is detachable, and has a threaded sealing port on its upper end, by engaging the threaded sealing port, low vacuum (e.g. 10⁻⁴ Pa) is allowed. The detachable quartz reaction tube 21 can facilitate sample change, after placing the sample, the quartz reaction tube 21 is placed inside the electron paramagnetic resonance spectrometer 1. The quartz reaction tube 21 can transmit light or be penetrated by light, which can realize the test of material under the light-adding condition provided by the illumination unit 5 during the reaction process, and the quartz reaction tube 21 will not affect the experimental results. In order to ensure that the gas is fully in contact with the sample, the gas is directly introduced into the bottom of the quartz reaction tube 21, wherein quartz or silica wool is added into the quartz reaction tube 21, and then the sample is placed, thereby realizing aeration during the reaction process and material testing under vacuum conditions. The gas inlet pipe in the quartz reaction tube 21 is a soft rubber tube, and the soft rubber tube is moderately soft and hard.

The outer diameter of the connecting part 22 is 20 mm and the length is 66 mm. The connecting part 22 plays a load-bearing role, and is made of polyoxymethylene (optionally, the connecting part 22 can be made of other high molecular polymers, as long as it is non-magnetic). The electron paramagnetic resonance spectrometer 1 has an instrument matching bayonet, and the connecting part 22 is connected with the instrument matching bayonet, so that the in-situ vacuum reaction chamber 2 is connected with the electron paramagnetic resonance spectrometer 1. The upper end of the connecting part 22 and the lower end of the stainless steel pipeline 24 are welded with stainless steel so that they cannot be disassembled, and the lower end of the connecting part 22 is connected with the quartz reaction tube 21 by threaded connection.

The gas inlet pipeline 23 is used to introduce gas into the in-situ vacuum reaction chamber 2, the material is polyoxymethylene (optionally, the gas inlet pipeline 23 can be made of other high molecular polymers, which is non-magnetic), and the length is 150-200 mm. A flange valve at the upper end of the gas inlet pipeline 23 ensures the vacuum in the pipes, the gas inlet pipeline 23 extends slightly beyond the connecting part 22, thereby the gas inlet pipeline 23 being connected with the soft rubber tube and extending deep into the bottom of the quartz reaction tube 21. A central protrusion of the gas inlet pipeline 23 is used for the connection with the flange valve, and a portion of the gas inlet pipeline 23, which locates below the flange valve, has an outer diameter smaller than the inner diameters of any one of the stainless steel pipeline 24, the connecting part 22 and the quartz reaction tube 21. An exhaust channel is formed between an outer wall of the inlet pipe 23 and inner walls of the quartz reaction tube 21, the stainless steel pipeline 24 and the connecting part 22.

The valve a 25 is connected with the stainless steel pipeline 24, one end of the valve a 25 is provided with a vacuum suction port, and the vacuum suction port is connected to a two-stage vacuum pump (the two-stage vacuum pump includes a mechanical pump and a molecular pump), the connection method is stainless steel screw connection, thereby ensuring that the high vacuum inside the in-situ vacuum reaction chamber 2 can reach 10⁻¹ to 10⁻⁵ Pa. A low vacuum gauge is connected to the pipeline at the pump port end of the two-stage vacuum pump, and the vacuum level in the system can be monitored in real time.

The valve b 26 is also connected with the stainless steel pipeline 24, and one end of the valve b 26 is a gas outlet for discharging the reaction tail gas, the valve b 26 is connected to a gas flow display device through a pipeline, and the gas outlet is tightened through a stainless steel screw.

The composite vacuum gauge 27 is also connected to the stainless steel pipeline 24, and can automatically switch for the different vacuum detection ranges according to the actual situation. In addition, the low vacuum gauge and the high vacuum gauge can be individually used. When the indicator of the low vacuum gauge is stable at about 0.5 Pa, the high vacuum gauge is used to detect the high vacuum in the reactor.

The gas supply unit 3 is connected to the gas inlet of the in-situ vacuum reaction chamber 2 through the mixing bottle 7, and is used for gas distribution for the in-situ vacuum reaction chamber 2.

The vacuum unit 4 is composed of a two-stage pump, the two-stage pump includes a mechanical pump and a molecular pump. The mechanical pump is initially pumped to a low vacuum, and then the molecular pump is pumped to a high vacuum environment. The entire gas channel of the in-situ vacuum reaction chamber 2 can be vacuumized, so as to eliminate the mutual interference between the gas components on the test environment, and at the same time, the detection of the instrument under vacuum conditions can also be realized.

The illumination unit 5 is an external unit, and the electron paramagnetic resonance spectrometer 1 has a window, at its front side, and the window can be disassembled. The front-end window of the electron paramagnetic resonance spectrometer 1 can be disassembled, and light adding devices such as lamps can be extended into the electron paramagnetic resonance spectrometer 1, so as to realize the light adding conditions during detection. But it should be noted that if it is necessary to arrange it into the electron paramagnetic resonance spectrometer 1, the light adding device needs to be made of non-magnetic material; otherwise, the light adding device is only allowed to be placed outside the electron paramagnetic resonance spectrometer 1.

The temperature control unit 6 is connected to the electron paramagnetic resonance spectrometer 1 through a pipeline, and the use of the temperature control unit 6 can realize the real-time monitoring of materials with the temperature changes, under the in-situ reaction condition of the electron paramagnetic resonance spectrometer 1 during the test process.

The in-situ vacuum reaction system for dynamically detecting defects of the present disclosure can realize the following functions:

1. Simulate photocatalytic test conditions.

After placing a test sample in the in-situ vacuum reaction chamber 2, closing the valve a 25 and a vacuum gauge. A catalytic sample is placed inside an instrument cavity of the electron paramagnetic resonance spectrometer 1. Closing the valve b 26, opening the valve a 25, and opening the two-stage pump to apply vacuum so that the adsorbed substances on the surface of the samples (including the test sample and the catalytic sample) can be removed, and at the same time the adsorbed gas molecules in the pipeline can be removed. Then, the vacuum unit 4 is closed, and the gas molecules for catalytic reactions are introduced through the gas inlet pipe 23. When the low vacuum gauge shows a normal pressure reading, the valve b 26 is opened. The external illumination unit 5 is turned on after the gas is normally introduced, and the changes of the catalyst sample under the reaction conditions can be monitored in real time.

2. Vacuum condition test.

A catalytic sample is placed inside an instrument cavity of the electron paramagnetic resonance spectrometer 1. Close the valve b 26, open the valve a 25, and open the two-stage vacuum pump. After pumping to a low vacuum, the external illumination unit 5 can be turned on, and the influence of the light source on the material itself under vacuum conditions can be monitored in real time.

3. The real-time monitoring of the reaction process can be realized by the design device.

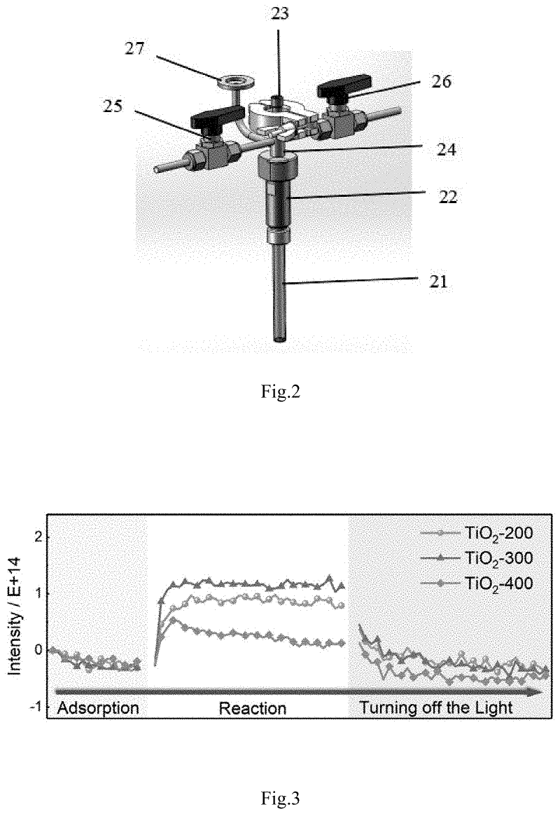

FIG. 3 is a graph of the real-time defect signal changes measured by in-situ EPR for TiO2 materials with different initial defects under photocatalytic adsorption, reaction and light-off conditions. As shown in FIG. 3, the defect content changes dynamically throughout the photocatalytic reaction process. During the first 15 minutes of adsorption, the defect content of the catalyst is showed with a slight decrease, which means that the adsorption of molecules on the surface defects inhibits the generation of some defect signals; however, after the light was turned on, the content of defects increased significantly almost instantaneously; after the light was turned off, the defect concentration of the catalyst returned to the initial state with the disappearance of the excitation source. These findings are based on the design of the in-situ vacuum reaction chamber.

Those of ordinary skill in the art will appreciate that the embodiments described herein are intended to assist readers in understanding the principles of the present disclosure, and it should be understood that the protection scope of the present disclosure is not limited to such specific statements and embodiments. Those skilled in the art can make various other specific modifications and combinations without departing from the present disclosure according to the technical teaching disclosed in the present disclosure, and these modifications and combinations still fall within the protection scope of the present disclosure.

What is claimed is:

1. An in-situ vacuum reaction system for dynamically detecting defects, comprising an electron paramagnetic resonance spectrometer, an in-situ vacuum reaction chamber, a gas supply unit, a vacuum unit, an illumination unit, a temperature control unit and a mixing bottle, wherein the in-situ vacuum reaction chamber is arranged inside a detection cavity of the electron paramagnetic resonance spectrometer, the gas supply unit is connected to the mixing bottle through a first pipeline, and the mixing bottle is connected to a gas inlet of the in-situ vacuum reaction chamber through a second pipeline, the vacuum unit is connected to the gas inlet of the in-situ vacuum reaction chamber through a third pipeline, the illumination unit is arranged corresponding to a detachable window of the electron paramagnetic resonance spectrometer, and the temperature control unit is connected to the electron paramagnetic resonance spectrometer through a fourth pipeline.

2. The in-situ vacuum reaction system for dynamically detecting defects of claim 1, wherein the in-situ vacuum reaction chamber comprises a quartz reaction tube, a connecting part, a gas inlet pipeline, a stainless steel pipeline, a first valve, a second valve and a composite vacuum gauge, an upper end of the connecting part is connected with a lower end of the stainless steel pipeline, and a lower end of the connecting part is connected with the quartz reaction tube by a threaded connection, an exhaust channel is formed between an outer wall of the gas inlet pipeline and inner walls of the quartz reaction tube, the stainless steel pipeline and the connecting part, and the first valve, the second valve and the composite vacuum gauge are connected with the stainless steel pipeline.

3. The in-situ vacuum reaction system for dynamically detecting defects of claim 2, wherein an outer diameter of the quartz reaction tube is 5-10 mm, and an inner diameter of the quartz reaction tube is 4-9 mm.

4. The in-situ vacuum reaction system for dynamically detecting defects of claim 3, wherein, a length of the quartz reaction tube is 90-110 mm.

5. The in-situ vacuum reaction system for dynamically detecting defects of claim 2, wherein, an outer diameter of the connecting part is 20 mm.

6. The in-situ vacuum reaction system for dynamically detecting defects of claim 5, wherein, a length of the connecting part is 66 mm.

7. The in-situ vacuum reaction system for dynamically detecting defects of claim 2, wherein, the gas inlet pipeline is made of polyoxymethylene.

8. The in-situ vacuum reaction system for dynamically detecting defects of claim 7, wherein, a length of the gas inlet pipeline is 150-200 mm.

9. The in-situ vacuum reaction system for dynamically detecting defects of claim 1, wherein, the vacuum unit comprises a two-stage pump.

10. The in-situ vacuum reaction system for dynamically detecting defects of claim 9, wherein, the two-stage pump comprises a mechanical pump and a molecular pump.
